(19) United States
(12) Patent Application Publication
(10) Pub. No.: US 2026/0096188 A1
(43) Pub. Date: Apr. 2, 2026

(54) SEMICONDUCTOR DEVICE AND MANUFACTURING METHOD THEREOF

(71) Applicant: Samsung Electronics Co., Ltd., Suwon-si (KR)

(72) Inventors: Byeolhae Eom, Suwon-si (KR); Myung Gil Kang, Suwon-si (KR); Taewoo Uhm, Suwon-si (KR)

(21) Appl. No.: 19/090,968

(22) Filed: Mar. 26, 2025

(30) Foreign Application Priority Data
Sep. 27, 2024 (KR) 10-2024-0132051

(51) Int. Cl. H10D 84/80; H01L 21/768; H01L 23/522; H10D 84/01; H10D 89/10

(52) U.S. Cl. CPC H10D 84/811; H10D 84/0109; H10D 89/10; H10W 20/056; H10W 20/42

(57) ABSTRACT

A semiconductor device includes a base insulating layer which includes a first region and a second region, a passive element which includes a first conductive region and a second conductive region on the first region of the base insulating layer, and a transistor on the second region of the base insulating layer. A portion of the first conductive region and a portion of the second conductive region of the passive element may be separated by a first trench, and the transistor may be insulated by a second trench. A second depth of the second trench in a first direction perpendicular to a surface of the base insulating layer may be greater than a first depth of the first trench in the first direction.

### CROSS-REFERENCE TO RELATED APPLICATION

This application claims priority under 35 U.S.C. § 119 to and the benefit of Korean Patent Application No. 10-2024-0132051, filed in the Korean Intellectual Property Office on Sep. 27, 2024, the entire contents of which are incorporated herein by reference.

### BACKGROUND

The present disclosure relates generally to a semiconductor device and a manufacturing method for a semiconductor device.

As the demand for integrated circuits with high component density and performance increases, backside power distribution networks (BSPDNs) formed on an upper surface or under an upper surface level of a nanosheet transistor structure substrate have been introduced to address routing complexity in a back-end-of-line (BEOL).

In this way, the substrate under the transistor structure in the form of nanosheets is thinned to form BSPDN, so it becomes difficult to form passive components other than transistors on the substrate.

### SUMMARY

Embodiments of the present inventive concept attempt to provide a semiconductor device having a bulk-less structure and a BSPDN structure including a passive element together with a transistor including a channel layer in the form of nanosheets, and a manufacturing method therefor.

However, the problem to be solved by the embodiments is not limited to the above-described problem, and can be variously extended within the scope of the technical spirit included in the embodiments.

An embodiment of the present disclosure provides a semiconductor device including: a base insulating layer which includes a first region and a second region, a passive element which includes a first conductive region and a second conductive region on the first region of the base insulating layer, and a transistor on the second region of the base insulating layer. A portion of the first conductive region and a portion of the second conductive region of the passive element may be separated by a first trench, the transistor may be insulated by a second trench, and a depth of the second trench may be greater than a depth of the first trench.

An embodiment of the present disclosure provides a semiconductor device including: a base insulating layer which includes a first region and a second region, a passive element which includes a first conductive region and a second conductive region on the first region of the base insulating layer, and a transistor on the second region of the base insulating layer. At least one of the first conductive region or the second conductive region may be in a semiconductor substrate on the base insulating layer and a nanosheet structure on the semiconductor substrate.

An embodiment of the present disclosure provides a manufacturing method for a semiconductor device, including forming a nanosheet layer in which a plurality of first layers and a plurality of second layers are alternately stacked on a substrate including a bulk region and an active region on the bulk region, forming a first trench by removing portions of the nanosheet layer and the active region in the first region of the substrate, forming a second trench by removing the nanosheet layer and the active region in the second region of the substrate, forming a first conductive region and a second conductive region in the active region of the first region and the nanosheet layer, forming a transistor including the active region of the second region and the second layers, and removing the bulk region.

According to one or more embodiments of the present disclosure, it may be possible to provide a semiconductor device having a bulk-less structure and a BSPDN structure including a passive element together with a transistor including a channel layer in the form of nanosheets, and a manufacturing method therefor.

However, it is to be appreciated that the effect of the embodiments is not limited to the above-described effect, and may be variously extended without departing from the spirit and scope of the embodiments.

### BRIEF DESCRIPTION OF THE DRAWINGS

The above and other aspects, features, and advantages of the present disclosure will be more clearly understood from the following detailed description, taken in conjunction with the accompanying drawings, wherein like reference numerals (when used) indicate corresponding elements throughout the several views, and in which:

FIG. 1 illustrates a schematic cross-sectional view of a semiconductor device according to an embodiment;

FIG. 2 illustrates a schematic cross-sectional view of a semiconductor device according to an embodiment;

FIG. 3 illustrates a schematic cross-sectional view of a semiconductor device according to an embodiment;

FIG. 4 illustrates a schematic cross-sectional view of a semiconductor device according to an embodiment;

FIG. 5 illustrates a schematic cross-sectional view of a semiconductor device according to an embodiment;

FIG. 6 illustrates a schematic cross-sectional view of a semiconductor device according to an embodiment;

FIG. 7 illustrates a schematic cross-sectional view of a semiconductor device according to an embodiment; and

FIG. 8 to FIG. 13 each illustrate an intermediate process in an example manufacturing method for a semiconductor device according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar components throughout the specification.

The accompanying drawings are provided only in order to allow embodiments disclosed in the present specification to be easily understood and are not to be interpreted as limiting the spirit disclosed in the present specification, and it is to be understood that the embodiments include all modifications, equivalents, and substitutions without departing from the scope and spirit of this disclosure.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., may be exaggerated for clarity. In the drawings, for better understanding and ease of description, the thicknesses of some layers and areas may be exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or under the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, “connected” means that two or more components are not only directly connected, but two or more components may be connected indirectly through other components, physically connected as well as being electrically connected, or it may be referred to by different names depending on the location or function, but may mean integral.

Hereinafter, various embodiments and variations will be described in detail with reference to drawings.

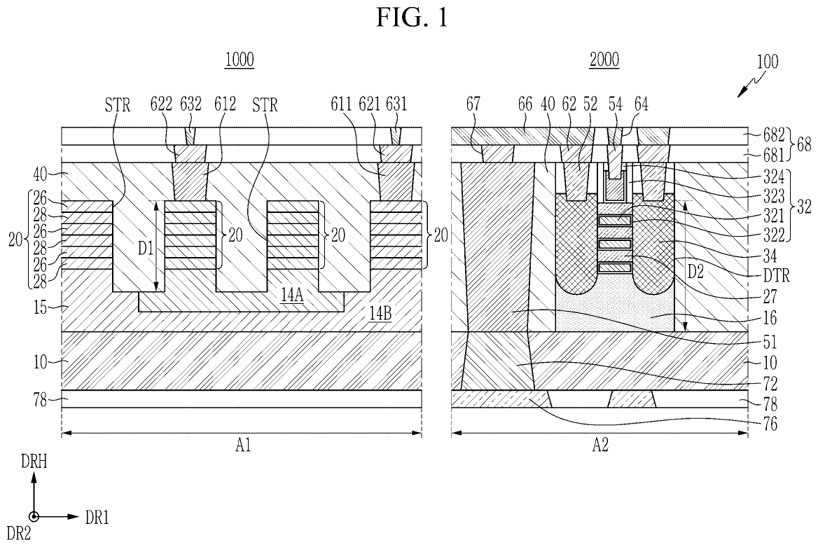

Hereinafter, a semiconductor device 100 according to an embodiment will be described with reference to FIG. 1. FIG. 1 illustrates a schematic cross-sectional view of a semiconductor device according to an embodiment.

Referring to FIG. 1, the semiconductor device 100 according to an embodiment may include a first region A1 and a second region A2. The first region A1 may include a passive element 1000, and the second region A2 may include a transistor 2000.

Each of the passive element 1000 and the transistor 2000 may be on a base insulating layer 10. For example, the passive element 1000 may be a PN diode having a bulk-less structure, and the transistor 2000 may have a backside power distribution network (BSPDN) structure.

The base insulating layer 10 may support the passive element 1000 and the transistor 2000.

In an embodiment, the base insulating layer 10 may be an entire region under the passive element 1000 and the transistor 2000. For example, the base insulating layer 10 may have planes extending in first and second directions DR1 and DR2 parallel to a surface of the base insulating layer 10 and crossing each other, and may have a constant thickness along a height (i.e., vertical) direction DRH perpendicular to the surface of the base insulating layer 10.

The base insulating layer 10 may include an insulating material. For example, the base insulating layer 10 may include a silicon oxide (SiOₓ), a silicon nitride (SiNₓ), a silicon oxynitride (SiONₓ), or a combination thereof, but the embodiment is not limited thereto.

A back insulating layer 78 may be under the base insulating layer 10. However, the embodiment is not limited thereto, and the back insulating layer 78 may be omitted.

The passive element 1000 including a first conductive region 14A and a second conductive region 14B having opposite conductive types on the base insulating layer 10 in the first region A1. The passive element 1000 may be a diode including the first conductive region 14A and second conductive region 14B, referred to collectively as 14.

The first conductive region 14A and the second conductive region 14B may each include a semiconductor material. The first conductive region 14A and the second conductive region 14B may each include at least one of a group IV semiconductor, a group III-V compound semiconductor, or a group II-VI compound semiconductor. For example, the first conductive region 14A and the second conductive region 14B may each include at least one of silicon (Si), germanium (Ge), silicon germanium (SiGe), silicon carbide (SiC), gallium arsenide (GaAs), indium arsenide (InAs), or indium phosphide (InP), although embodiments are not limited thereto.

The first conductive region 14a and the second conductive region 14B may include a crystalline semiconductor substrate, e.g., a single crystalline semiconductor substrate or a polycrystalline semiconductor. As another example, the first conductive region 14A and the second conductive region 14B may include an epitaxial semiconductor layer. If the first conductive region 14A and the second conductive region 14B included in the diode 14 include a crystalline semiconductor material, electrical characteristics of the passive element 1000 may be improved.

The first conductive region 14A may have a first conductive type by including a semiconductor material doped with a first conductive dopant, and the second conductive region 14B may have a second conductive type by including a semiconductor material doped with a second conductive dopant. For example, the first conductive dopant may be P-type and the second conductive dopant may be N-type. Alternatively, the first conductive dopant may be N-type and the second conductive dopant may be P-type.

The first conductive region 14A and the second conductive region 14B adjacent to each other may form a PN diode 14.

The passive element 1000 may include the second conductive region 14B and the first conductive region 14A on the base insulating layer 10 and adjacent to each other along the height direction DRH, and the second conductive region 14B may be under the first conductive region 14A and may surround the first conductive region 14A. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround”another layer which it encircles.

The first conductive region 14A may include a first portion doped with a dopant in a semiconductor substrate 15 and a second portion doped with a dopant in a nanosheet structure 20 on the first portion.

Similarly, the second conductive region 14B may include a first portion doped with a dopant in the semiconductor substrate 15 and a second portion doped with a dopant in the nanosheet structure 20 on the first portion.

The nanosheet structure 20 may include a plurality of first layers 26 and a plurality of second layers 28 that are alternately stacked in the height direction DRH. The first layers 26 and the second layers 28 may include a semiconductor material. For example, the first layers 26 may include silicon (Si), and the second layers 28 may include silicon germanium (SiGe). However, the embodiment is not limited thereto, and the first layers 26 and the second layers 28 may include different materials.

The second portion of the first conductive region 14A and the second portion of the second conductive region 14B may be separated from each other in the first direction DR1 by a separation trench STR and an insulating layer 40 in the separation trench STR.

The separation trench STR may extend through the nanosheet structure 20 and a portion of the semiconductor substrate 15. The separation trench STR may have a first depth D1 in the height direction DRH from an upper surface of the nanosheet structure 20.

In the illustrated embodiment, areas of the first conductive region 14A and the second conductive region 14B included in the diode 14 are illustrated as being different from each other, but the embodiment is not limited thereto, and according to another embodiment, the first conductive region 14A and the second conductive region 14B included in the diode 14 may have a same area.

Furthermore, in an embodiment, the semiconductor device 100 may include a plurality of diodes 14, and the first conductive region 14A and/or the second conductive region 14B included in the diodes 14 may have different areas or different arrangements.

The insulating layer 40 may be on the passive element 1000 of the first region A1, and a front insulating layer 68 may be on the insulating layer 40.

The front insulating layer 68 may include a first front insulating layer 681 and a second front insulating layer 682 on the first front insulating layer 681. However, the embodiment is not limited thereto, and the front insulating layer 68 may be formed of one or more insulating layers.

For example, the first front insulating layer 681 and the second front insulating layer 682 may include at least one of a silicon oxide, a silicon nitride, a silicon oxynitride, or a low dielectric constant material. However, the embodiment is not limited thereto, and the first front insulating layer 681 and the second front insulating layer 682 may include various materials or may have various structures, and a boundary between the first front insulating layer 681 and the second front insulating layer 682 may or may not be clearly identified.

The second portion of the second conductive region 14B may be connected to a first contact via 611 in the insulating layer 40, a second contact via 621 in the first front insulating layer 681, and a third contact via 631 in the second front insulating layer 682, and a predetermined electrical signal may be applied from the outside to the second conductive region 14B of the passive element 1000 through the first contact via 611, the second contact via 621, and the third contact via 631.

The first portion of the second conductive region 14A may be connected to a first contact via 612 in the insulating layer 40, a second contact via 622 in the first front insulating layer 681, and a third contact via 632 in the second front insulating layer 682, and a predetermined electrical signal may be applied from the outside to the first conductive region 14A of the passive element 1000 through the first contact via 612, the second contact via 622, and the third contact via 632.

The transistor 2000 may be on the base insulating layer 10 of the second region A2.

The transistor 2000 may include an active pattern 16, a plurality of channel layers 27, a gate structure 32, and source and drain patterns 34 on the base insulating layer 10.

The active pattern 16 and the channel layers 27 intersecting the gate structure 32 may be a channel region of the transistor 2000.

The channel layers 27 may be a same layer as the first layer 26 of the nanosheet structure 20.

The channel layers 27 may be arranged to be spaced apart from each other along the height direction DRH on the active pattern 16. Each of the channel layers 27 may have a nanosheet shape with a thickness of nanometer level (e.g., 1 nm to 10 nm), and may be a semiconductor pattern containing a semiconductor material. However, the embodiment is not limited to thereto, and shapes of the channel layers 27 may be modified in various ways, and a thickness of the channel layers 27 may be less than 1 nm or more than 10 nm.

The active pattern 16 may be a crystalline semiconductor substrate including a semiconductor material, e.g., a monocrystalline semiconductor substrate or a polycrystalline semiconductor substrate. The active pattern 16 may include a crystalline semiconductor substrate and an epitaxial layer grown from the crystalline semiconductor substrate and including a semiconductor material. The channel layers 27 may include an epitaxial layer containing a semiconductor material.

For example, a semiconductor substrate included in the active pattern 16 may include at least one of a group IV semiconductor, a group III-V compound semiconductor, or a group II-VI compound semiconductor. For example, the semiconductor substrate included in the active pattern 16 may include at least one of Si, Ge, SiGe, SiC, GaAs, InAs, or InP. The semiconductor substrate and/or the epitaxial layer included in the active pattern 16 may include a same semiconductor material as that of the semiconductor substrate and/or the epitaxial layer provided in the diode 14.

For example, the channel layers 27 may include at least one of a group IV semiconductor, a group III-V compound semiconductor, or a group II-VI compound semiconductor. The channel layers 27 may include at least one of Si, Ge, SiGe, SiC, GaAs, InAs, or InP, for example, at least one of Si, Ge, or SiGe. Each of the channel layers 27 may include a same material as that of the active pattern 16 or a different material from that of the active pattern 16.

As an example, the active pattern 16 and the channel layers 27 may include Si or SiGe. For example, the active pattern 16 may include Si, and the channel layers 27 may include SiGe. However, the embodiment is not limited thereto, and the active pattern 16 and the channel layers 27 may include different materials.

A material of the active pattern 16, a shape, a thickness, and a material of the channel layer 27, or a number of channel layers 27 constituting one channel structure may be changed in various ways.

The gate structure 32 may be on the channel layers 27.

The gate structure 32 may include a gate electrode 321, a gate insulating layer 322, a gate spacer 323, and a gate capping layer 324.

The gate electrode 321 may surround each of the channel layers 27, and may be on the channel layers 27.

The gate insulating layer 322 may be disposed between the gate electrode 321 and the channel layers 27. In an embodiment, the gate insulating layer 322 may be between the active pattern 16 and the channel layers 27 and the gate electrode 321, and may be between the gate electrode 321 and the gate spacer 323.

The gate electrode 321 and the gate insulating layer 322 surrounding each of the channel layers 27 may have a same height as that of the second layer 28 of the nanosheet structure 20.

The gate spacer 323 may be on a side surface of the gate electrode 321 to insulate the source and drain pattern 34 and/or a first contact via 52 from the gate electrode 321. For example, the gate spacer 323 may be on a side surface of the gate electrode 321 on the channel layer 27, and may not be on the side surface of the channel layer 27.

The gate capping layer 324 may be on the gate electrode 321. In the illustrated embodiment, the gate spacer 323 is on a side surface of the gate capping layer 324, but the embodiment is not limited thereto, and the gate capping layer 324 may be on the gate spacer 323. In the embodiment, a front surface of the gate capping layer 324 may be on a same plane as a front surface of the first contact via 52 or the insulating layer 40, but the embodiment is not limited thereto, and the front surface of the gate capping layer 324 may be on a different plane from the front surface of the first contact via 52 or the insulating layer 40.

The gate electrode 321 may include a conductive material. For example, the gate electrode 321 may include at least one of a metal, a metal alloy, a metal nitride, a metal silicide, or a doped semiconductor material. Herein, the metal or metal alloy included in the gate electrode 321 may include at least one of tungsten, molybdenum, aluminum, copper, or cobalt, and the metal nitride included in the gate electrode 321 may include at least one of a tungsten nitride, a molybdenum nitride, a titanium nitride, or a tantalum nitride. The gate electrode 321 may further include an oxidized metal oxide or a metal oxynitride, or the gate electrode 321 may be formed to include multiple layers.

The gate insulating layer 322 may include an oxide, a nitride, or a high dielectric constant material. The high dielectric constant material may indicate a dielectric material having a higher dielectric constant than that of the silicon oxide. For example, the gate insulating layer 322 may include at least one of a silicon oxide, a silicon nitride, a silicon nitride, a hafnium oxide layer, an aluminum oxide layer, or a tantalum oxide layer. The gate insulating layer 322 may be formed to include a plurality of insulating layers.

The gate spacer 323 may include at least one of a silicon oxide, a silicon nitride, or a silicon nitride, or may further include carbon. For example, the gate spacer 323 may include a low dielectric constant material. The gate spacer 323 may include multiple layers. The gate capping layer 324 may include at least one of a silicon oxide, a silicon nitride, or a silicon oxynitride.

The embodiment is not limited thereto, and the gate electrode 321, the gate insulating layer 322, the gate spacer 323, or the gate capping layer 324 may include different materials or have other various structures.

The source and drain pattern 34 may be at opposite sides of the active pattern 16 and the channel layer 27.

The source and drain pattern 34 may constitute a source region or a drain region of the transistor 2000.

The source and drain patterns 34 may include an epitaxial layer formed by a selective epitaxial growth (SEG) process in a recessed portion of the active pattern 16. The source and drain patterns 34 may have an angular shape, but the embodiment is not limited thereto, and the source and drain patterns 34 may have various shapes, such as a polygon, a circle, an ellipse, a rounded shape, etc.

For example, the source and drain patterns 34 may include at least one of Si, Si—Ge, or SiC, and may further include impurities such as arsenic (As) or phosphorus (P). According to another embodiment, the source and drain patterns 34 may include a plurality of portions having different materials or different compositions. The embodiment is not limited thereto, and the source and drain patterns 34 may include various materials and have various structures.

The transistor 2000 may be insulated from another semiconductor element by an insulating trench DTR and an insulating layer 40 in the insulating trench DTR.

The insulating trench DTR may be in the channel layers 27 and the active pattern 16, and the insulating trench DTR may have a second depth D2 in the height direction DRH from an upper surface of the uppermost channel layer 27. The second depth D2 may be different from the first depth D1, and the second depth D2 may be greater than the first depth D1.

The insulating trench DTR may not overlap the semiconductor substrate forming the active pattern 16 along the height direction DRH. As used herein, “an element A overlapping an element B in a direction X” (or similar language) means that there is at least one line that extends in the direction X and intersects both the elements A and B. The insulating trench DTR may be formed to extend through the channel layer 27 and the active pattern 16 in the height direction DRH from an upper surface of the channel layer 27 at an uppermost portion of the transistor 2000 to the base insulating layer 10. The insulating trench DTR may extend to the base insulating layer 10.

The insulating layer 40 may be not only in the insulating trench DTR but also on the transistor 2000 of the second region A2, and the front insulating layer 68 may be on the insulating layer 40.

The front insulating layer 68 may include a first front insulating layer 681 and a second front insulating layer 682. However, the embodiment is not limited thereto, and the front insulating layer 68 may be formed of one or more insulating layers.

The first contact via 52 may be in the insulating layer 40, may be connected to the source and drain patterns 34, and a second contact via 62 in the first front insulating layer 681 may be connected to the first contact via 52.

A front wiring layer 66 may be on the first front insulating layer 681, and the front wiring layer 66 may be connected to the second contact via 62.

A through-connector 51 extending in the height direction DRH through the insulating layer 40 in the insulating trench DTR may electrically connect the source and drain patterns 34 and a back wiring layer 76 through a third contact via 67 in the first front insulating layer 681 and connected to the front wiring layer 66, the second contact via 62 connected to the front wiring layer 66, the first contact via 52 connected to the second contact via 62, and a back contact via 72 formed on the base insulating layer 10.

A fourth contact via 54 may be connected to the gate electrode 321 by extending in the height direction DRH through the first front insulating layer 681, the insulating layer 40, and the gate capping layer 324. A fifth contact via 64 may be in the second front insulating layer 682, and may be connected to the fourth contact via 54.

For simplicity and clarity of understanding, the drawing shows that the front wiring layer 66 includes one layer connected to the through-connector 51 through the contact via 67, but the embodiment is not limited thereto, and the front wiring layer 66 may further include one or more additional wiring layers.

According to an embodiment, the semiconductor device 100 may include the first region A1 including the passive element 1000 and the second region A2 including the transistor 2000, the passive element 1000 and the transistor 2000 may be on the base insulating layer 10, the passive element 1000 may include the semiconductor substrate 15 on the base insulating layer 10 and the first conductive region 14A and the second conductive region 14B of the nanosheet structure 20, and the transistor 2000 may include the active pattern 16 on the base insulating layer 10, the channel layers 27, the gate structure 32, and the source and drain pattern 34.

The first region A1 may include the separation trench STR that extends through the nanosheet structure 20 and a portion of the semiconductor substrate 15, and the second region A2 may include the insulating trench DTR that extends through the active pattern 16 having a same layer as the semiconductor substrate 15 and the channel layers 27 having same layers as the nanosheet structure 20. The separation trench STR may have a first depth D1 in the height direction DRH from an upper surface of the nanosheet structure 20, the insulation trench DTR may have a second depth D2 in the height direction DRH from an upper surface of an uppermost layer of the channel layers 27, the second depth D2 may be different from the first depth D1, and the second depth D2 may be greater than the first depth D1.

The first conductive region 14A and the second conductive region 14B of the passive element 1000 may be separated from each other by the insulating layer 40 in the separation trench STR, and the transistor 2000 may be separated from other semiconductor elements by the insulating layer 40 in the insulating trench DTR.

The first region A1 including the passive element 1000 may have a separation trench STR having a relatively low (i.e., shallow) first depth D1 so that a portion of the semiconductor substrate 15 may remain. Accordingly, the first conductive region 14A and the second conductive region 14B may be formed in the remaining semiconductor substrate 15, and the first conductive region 14A and the second conductive region 14B may be in contact with the base insulating layer 10. This may allow the passive element 1000 to have a bulk-less structure.

The second region A2 including the transistor 2000 may have an insulating trench DTR having a second depth D2 that penetrates (i.e., extends in or through) the substrate and has a relatively deep second depth, so that no substrate may be left around the transistor 2000, allowing for a back-side power distribution network (BSPDN) structure.

In this way, the semiconductor device 100 according to the embodiment may include the passive element 1000 in the first region A1 and the transistor 2000 including the channel layer 27 of a nanosheet in the second region A2, and may have a bulk-less structure and a back-end power distribution network (BSPDN) structure.

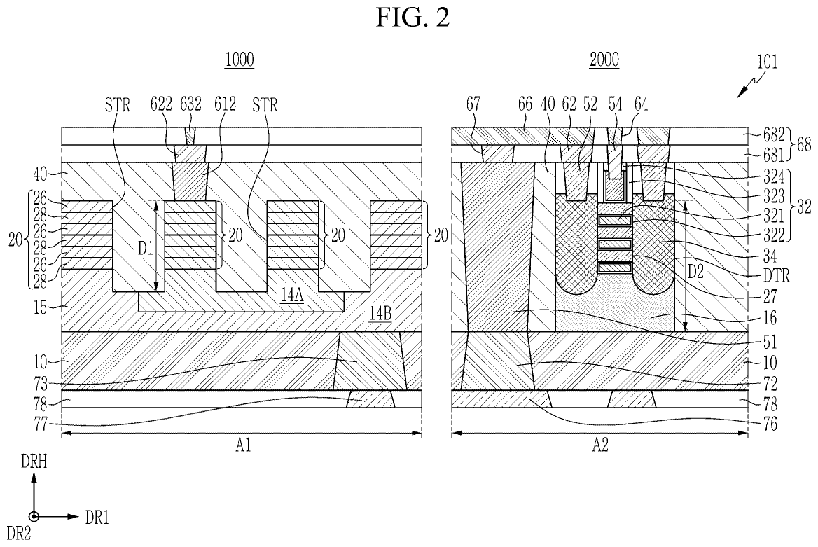

Then, a semiconductor device 101 according to an embodiment will be described with reference to FIG. 2. FIG. 2 illustrates a schematic cross-sectional view of a semiconductor device according to an embodiment.

Referring to FIG. 2, the semiconductor device 101 according to the present embodiment is similar to the semiconductor device 100 according to the previously described embodiment. Detailed descriptions of the same components will be omitted.

Referring to FIG. 2, the semiconductor device 101 according to the present embodiment may include a first region A1 including the passive element 1000 and a second region A2 including the transistor 2000.

The passive element 1000 and the transistor 2000 may be on a base insulating layer 10. For example, the passive element 1000 may be a PN diode having a bulk-less structure, and the transistor 2000 may have a backside power distribution network (BSPDN) structure.

For a structure of the passive element 1000 and the transistor 2000 according to the present embodiment, the above-described description of the passive element 1000 and the transistor 2000 of the semiconductor device 100 according to the previously described embodiment shown in FIG. 1 may be applied.

However, unlike in the semiconductor device 100 according to the previously described embodiment, instead of the first contact via 611, the second contact via 621, and the third contact via 631, the semiconductor device 101 according to the present embodiment may be connected to the second conductive region 14B of the passive element 1000 through a first back contact via 73 in the base insulating layer 10 and a second back contact via 77 in the back insulating layer 78, and a predetermined electrical signal may be applied from the outside to the second conductive region 14B.

According to an embodiment, the semiconductor device 101 may include the first region A1 including the passive element 1000 and the second region A2 including the transistor 2000, the passive element 1000 and the transistor 2000 may be on the base insulating layer 10, the passive element 1000 may include the semiconductor substrate 15 on the base insulating layer 10 and the first conductive region 14A and the second conductive region 14B of the nanosheet structure 20, and the transistor 2000 may include the active pattern 16 on the base insulating layer 10, the channel layers 27, the gate structure 32, and the source and drain pattern 34.

The first region A1 may include the separation trench STR that extends in the height direction DRH through the nanosheet structure 20 and a portion of the semiconductor substrate 15, and the second region A2 may include the insulating trench DTR that extends in the height direction DRH through the active pattern 16 having a same layer as the semiconductor substrate 15 and the channel layers 27 having same layers as a portion of the nanosheet structure 20. The separation trench STR may have a first depth D1 in the height direction DRH from an upper surface of the nanosheet structure 20, the insulation trench DTR may have a second depth D2 in the height direction DRH from an upper surface of an uppermost layer of the channel layers 27, the second depth D2 may be different from the first depth D1, and the second depth D2 may be greater than the first depth D1.

The first conductive region 14A and the second conductive region 14B of the passive element 1000 may be separated from each other by the insulating layer 40 in the separation trench STR, and the transistor 2000 may be separated from other semiconductor elements by the insulating layer 40 in the insulating trench DTR.

The first region A1 including the passive element 1000 may have a separation trench STR having a relatively low (i.e., shallow) first depth D1 so that a portion of the semiconductor substrate 15 may remain. Accordingly, the first conductive region 14A and the second conductive region 14B may be formed in the remaining semiconductor substrate 15, and this allows the passive element 1000 to have the bulk-less structure.

The second region A2 where the transistor 2000 is located may include an insulating trench DTR having a second depth D2 that penetrates the substrate and has a relatively deep second depth, so that no substrate may be left around the transistor 2000, allowing for a back-side power distribution network (BSPDN) structure.

In this way, the semiconductor device 101 according to the embodiment may include the passive element 1000 in the first region A1 and the transistor 2000 including the channel layer 27 in the form of a nanosheet in the second region A2, and may have a bulk-less structure and a back-end power distribution network (BSPDN) structure.

Many of the features of the semiconductor device 100 according to the above-described embodiment of FIG. 1 are all applicable to the semiconductor device 101 according to the present embodiment shown in FIG. 2.

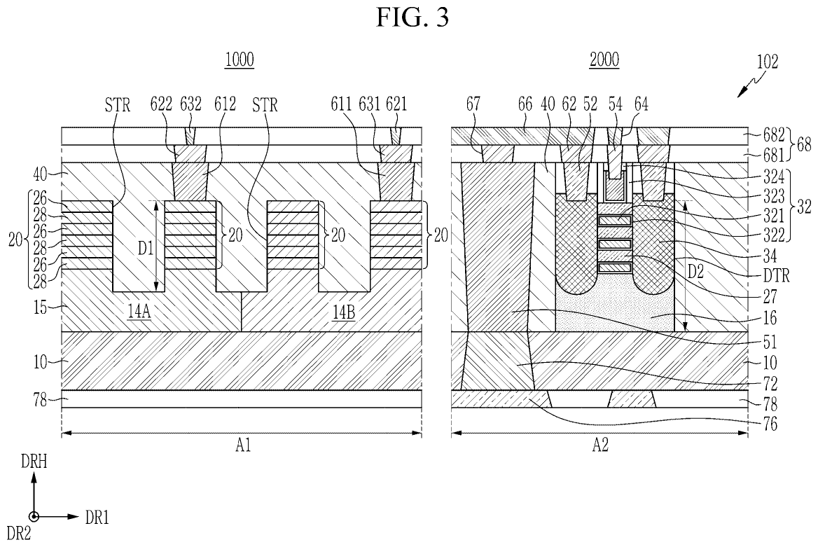

Hereinafter, a semiconductor device 102 according to an embodiment will be described with reference to FIG. 3. FIG. 3 illustrates a schematic cross-sectional view of a semiconductor device according to an embodiment.

Referring to FIG. 3, the semiconductor device 102 according to the present embodiment is similar to the semiconductor devices 100 (FIG. 1) and 101 (FIG. 2) according to the embodiments described above. Detailed descriptions of the same components will be omitted.

Referring to FIG. 3, the semiconductor device 102 according to the present embodiment may include a first region A1 including the passive element 1000 and a second region A2 including the transistor 2000.

The passive element 1000 and the transistor 2000 may be on a base insulating layer 10. For example, the passive element 1000 may be a PN diode having a bulk-less structure, and the transistor 2000 may have a backside power distribution network (BSPDN) structure.

For a structure of the passive element 1000 and the transistor 2000 of the semiconductor device 102 according to the present embodiment, the above-described description of the passive element 1000 and the transistor 2000 of the semiconductor device 100 according to the previously described embodiment may be applied.

The passive element 1000 and the transistor 2000 may be on the base insulating layer 10.

The transistor 2000 may include an active pattern 16, a plurality of channel layers 27, a gate structure 32, and source and drain patterns 34 on the base insulating layer 10.

The passive element 1000 may include the semiconductor substrate 15 on the base insulating layer 10 and the first conductive region 14A and the second conductive region 14B in the nanosheet structure 20.

Unlike the passive element 1000 of the semiconductor devices 100 and 101 according to the embodiments described above, in the passive element 1000 of the semiconductor device 102 according to the embodiment, the first conductive region 14A and the second conductive region 14B may be adjacent to each other along the first direction DR1, which is a horizontal direction, rather than being adjacent along the height direction DRH.

According to the embodiment, the first region A1 of the semiconductor device 102 may include the separation trench STR that extends in the height direction DRH through the nanosheet structure 20 and in a portion of the semiconductor substrate 15, and the second region A2 of the semiconductor device 102 may include the insulating trench DTR that extends in the height direction DRH through the active pattern 16 having a same layer as the semiconductor substrate 15 and the channel layers 27 having same layers as a portion of the nanosheet structure 20.

The separation trench STR may have a first depth D1 in the height direction DRH from an upper surface of the nanosheet structure 20, the insulation trench DTR may have a second depth D2 in the height direction DRH from an upper surface of an uppermost layer of the channel layers 27, the second depth D2 may be different from the first depth D1, and the second depth D2 may be greater than the first depth D1.

The first conductive region 14A and the second conductive region 14B of the passive element 1000 may be separated from each other by the insulating layer 40 in the separation trench STR, and the transistor 2000 may be separated from other semiconductor elements by the insulating layer 40 in the insulating trench DTR.

In the illustrated embodiment, the nanosheet structure 20 in the first conductive region 14A may include a portion separated by the separation trench STR, and the nanosheet structure 20 in the second conductive region 14B may include a portion separated by the separation trench STR. However, the embodiment is not limited thereto, and the separation trench STR may not be formed in the nanosheet structure 20 in the first conductive region 14A, and the separation trench STR may not be formed in the nanosheet structure 20 in the second conductive region 14B.

The first region A1 including the passive element 1000 may have a separation trench STR having a relatively low (i.e., shallow) first depth D1, so that a portion of the semiconductor substrate 15 may remain. Accordingly, the first conductive region 14A and the second conductive region 14B may be formed in the remaining semiconductor substrate 15, and this allows the passive element 1000 to have the bulk-less structure.

The second region A2 where the transistor 2000 is located may include an insulating trench DTR having a second depth D2 that penetrates the substrate and has a relatively deep second depth, so that no substrate may be left around the transistor 2000, allowing for a back-side power distribution network (BSPDN) structure.

In this way, the semiconductor device 102 according to the embodiment may include the passive element 1000 in the first region A1 and the transistor 2000 including the channel layer 27 in the form of a nanosheet in the second region A2, and may have a bulk-less structure and a back-end power distribution network (BSPDN) structure.

Many of the features of the semiconductor devices 100 and 101 according to the above-described embodiment are all applicable to the semiconductor device 102 according to the present embodiment.

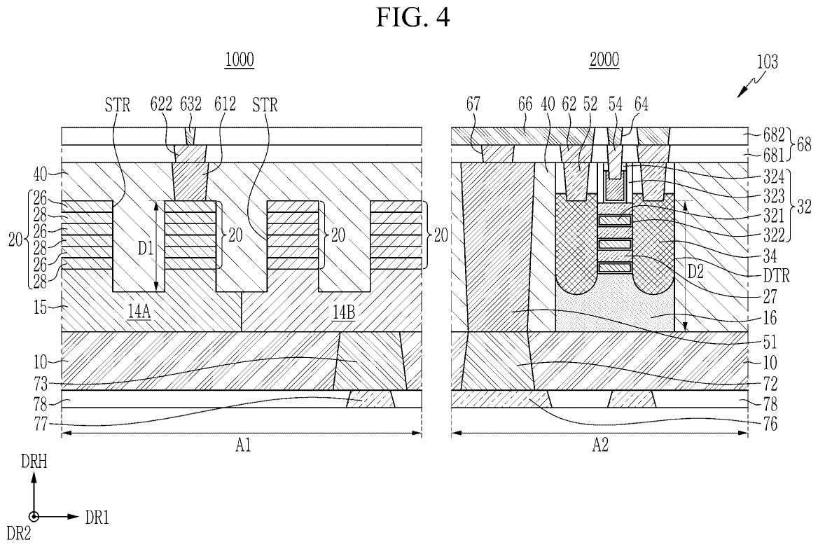

Hereinafter, a semiconductor device 103 according to an embodiment will be described with reference to FIG. 4. FIG. 4 illustrates a schematic cross-sectional view of a semiconductor device according to an embodiment.

Referring to FIG. 4, the semiconductor device 103 according to the embodiment is similar to the semiconductor devices 100, 101, and 102 according to the embodiments described above. Detailed descriptions of the same components will be omitted.

Referring to FIG. 4, the semiconductor device 103 according to the present embodiment may include a first region A1 including the passive element 1000 and a second region A2 including the transistor 2000.

The passive element 1000 and the transistor 2000 may be on a base insulating layer 10. For example, the passive element 1000 may be a PN diode having a bulk-less structure, and the transistor 2000 may have a backside power distribution network (BSPDN) structure.

For a structure of the passive element 1000 and the transistor 2000 according to the present embodiment, the above-described description of the passive element 1000 and the transistor 2000 of the semiconductor device 100 (see FIG. 1) according to the previously described embodiment may be applied.

According to the embodiment, in the passive element 1000 of the semiconductor device 103, the first conductive region 14A and the second conductive region 14B may be adjacent to each other along the first direction DR1, which is the horizontal direction.

However, unlike in the semiconductor device 102 according to the previously described embodiment of FIG. 3, instead of the first contact via 611, the second contact via 621, and the third contact via 631, the semiconductor device 103 according to the present embodiment may be connected to the second conductive region 14B of the passive element 1000 through a first back contact via 73 in the base insulating layer 10 and a second back contact via 77 in the back insulating layer 78, and a predetermined electrical signal may be applied from the outside to the second conductive region 14B.

According to an embodiment, the semiconductor device 103 may include the first region A1 including the passive element 1000 and the second region A2 including the transistor 2000, the passive element 1000 and the transistor 2000 may be on the base insulating layer 10, the passive element 1000 may include the semiconductor substrate 15 on the base insulating layer 10 and the first conductive region 14A and the second conductive region 14B in the nanosheet structure 20, and the transistor 2000 may include the active pattern 16 on the base insulating layer 10, the channel layers 27, the gate structure 32, and the source and drain patterns 34.

The first region A1 may include the separation trench STR that extends in the height direction DRH through the nanosheet structure 20 and a portion of the semiconductor substrate 15, and the second region A2 may include the insulating trench DTR that extends in the height direction DRH through the active pattern 16 having a same layer as the semiconductor substrate 15 and the channel layers 27 having same layers as a portion of the nanosheet structure 20. The separation trench STR may have a first depth D1 in the height direction DRH from an upper surface of the nanosheet structure 20, the insulation trench DTR may have a second depth D2 in the height direction DRH from an upper surface of an uppermost layer of the channel layers 27, the second depth D2 may be different from the first depth D1, and the second depth D2 may be greater than the first depth D1.

The first conductive region 14A and the second conductive region 14B of the passive element 1000 may be separated from each other by the insulating layer 40 in the separation trench STR, and the transistor 2000 may be separated from other semiconductor elements by the insulating layer 40 in the insulating trench DTR.

The first region A1 including the passive element 1000 may have a separation trench STR having a relatively low (i.e., shallow) first depth D1, so that a portion of the semiconductor substrate 15 may remain. Accordingly, the first conductive region 14A and the second conductive region 14B may be formed in the remaining semiconductor substrate 15, and this allows the passive element 1000 to have the bulk-less structure.

The second region A2 where the transistor 2000 is located may include an insulating trench DTR having a second depth D2 that penetrates the substrate and has a relatively deep second depth, so that no substrate may be left around the transistor 2000, allowing for a back-side power distribution network (BSPDN) structure.

In this way, the semiconductor device 103 according to the embodiment may include the passive element 1000 in the first region A1 and the transistor 2000 including the channel layer 27 in the form of a nanosheet in the second region A2, and may have a bulk-less structure and a back-end power distribution network (BSPDN) structure.

Many of the features of the semiconductor devices 100, 101, and 102 according to the above-described embodiments are all applicable to the semiconductor device 103 according to the present embodiment.

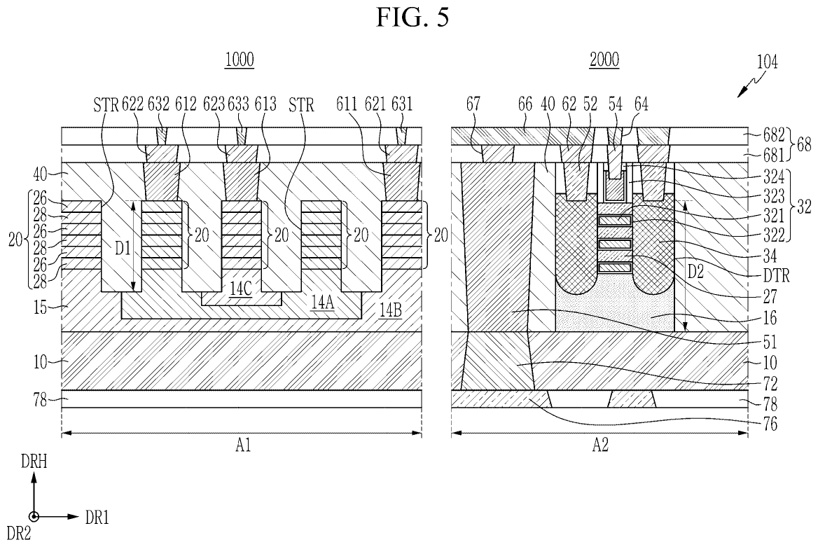

Hereinafter, a semiconductor device 104 according to an embodiment will be described with reference to FIG. 5. FIG. 5 illustrates a schematic cross-sectional view of a semiconductor device according to an embodiment.

Referring to FIG. 5, the semiconductor device 104 according to the present embodiment is similar to the semiconductor devices 100, 101, 102, and 103 according to the embodiments described above. Detailed descriptions of the same components will be omitted.

Referring to FIG. 5, the semiconductor device 104 according to the present embodiment may include a first region A1 including the passive element 1000 and a second region A2 including the transistor 2000.

The passive element 1000 and the transistor 2000 may be on a base insulating layer 10. For example, the passive element 1000 may be a PNP or NPN junction element having a bulk-less structure, and the transistor 2000 may have a backside power distribution network (BSPDN) structure.

For a structure of the passive element 1000 and the transistor 2000 of the semiconductor device 104 according to the present embodiment, the above-described description of the passive element 1000 and the transistor 2000 of the semiconductor device 100 according to the previously described embodiment shown in FIG. 1 may be applied.

The passive element 1000 and the transistor 2000 may be on the base insulating layer 10.

The transistor 2000 may include an active pattern 16, a plurality of channel layers 27, a gate structure 32, and source and drain patterns 34 on the base insulating layer 10.

The passive element 1000 may include a third conductive region 14C as well as the semiconductor substrate 15 on the base insulating layer 10 and the first conductive region 14A and the second conductive region 14B in the nanosheet structure 20. The third conductive region 14C may have a same conductivity type as that of the second conductivity type region 14B.

The second conductive region 14B of the semiconductor substrate 15 may be on a first surface of the first conductive region 14A under the first conductive region 14A, and the third conductive region 14C of the semiconductor substrate 15 may be on a second surface of the first conductive region 14A above the first conductive region 14A.

Unlike in the passive element 1000 of the semiconductor devices 100, 101, 102, and 103 according to the embodiments described above, the passive element 1000 of the semiconductor device 104 according to the present embodiment may be a PNP or NPN junction element.

The third conductive region 14C may include a first portion formed on the semiconductor substrate 15 and a second portion in the nanosheet structure 20 on the first portion, the second portion of the third conductive region 14C may be connected to the first contact via 613 in the insulating layer 40, the second contact via 623 in the first front insulating layer 681, and the third contact via 633 in the second front insulating layer 682, and a predetermined electrical signal may be applied from the outside to the third conductive region 14C of the passive element 1000 through the first contact via 613, the second contact via 623, and the third contact via 633.

According to the embodiment, the first region A1 of the semiconductor device 104 may have the separation trench STR that extends in the height direction DRH through the nanosheet structure 20 and a portion of the semiconductor substrate 15, and the second region A2 of the semiconductor device 104 may have the insulating trench DTR that extends in the height direction DRH through the active pattern 16 having a same layer as the semiconductor substrate 15 and the channel layers 27 having same layers as a portion of the nanosheet structure 20.

The separation trench STR may have a first depth D1 in the height direction DRH from an upper surface of the nanosheet structure 20, the insulation trench DTR may have a second depth D2 in the height direction DRH from an upper surface of an uppermost layer of the channel layers 27, the second depth D2 may be different from the first depth D1, and the second depth D2 may be greater than the first depth D1.

The first conductive region 14A, the second conductive region 14B, and the third conductive region 14C of the passive element 1000 may be separated from each other by the insulating layer 40 in the separation trench STR, and the transistor 2000 may be separated from other semiconductor elements by the insulating layer 40 in the insulating trench DTR.

The first region A1 including the passive element 1000 may be configured with the separation trench STR having a relatively low (i.e., shallow) first depth D1 so that a portion of the semiconductor substrate 15 may remain. Accordingly, the first conductive region 14A, the second conductive region 14B, and the third conductive region 14C may be formed in the remaining semiconductor substrate 15, and this allows the passive element 1000 to have the bulk-less structure.

The second region A2 where the transistor 2000 is located may include an insulating trench DTR having a second depth D2 in the height direction DRH that penetrates the substrate and has a relatively deep second depth, so that no substrate may be left around the transistor 2000, allowing for a back-side power distribution network (BSPDN) structure.

In this way, the semiconductor device 104 according to the embodiment may include the passive element 1000 in the first region A1 and the transistor 2000 including the channel layer 27 in the form of a nanosheet in the second region A2, and may have a bulk-less structure and a back-end power distribution network (BSPDN) structure.

Many of the features of the semiconductor devices 100, 101, 102, and 103 according to the above-described embodiment are all applicable to the semiconductor device 104 according to the present embodiment.

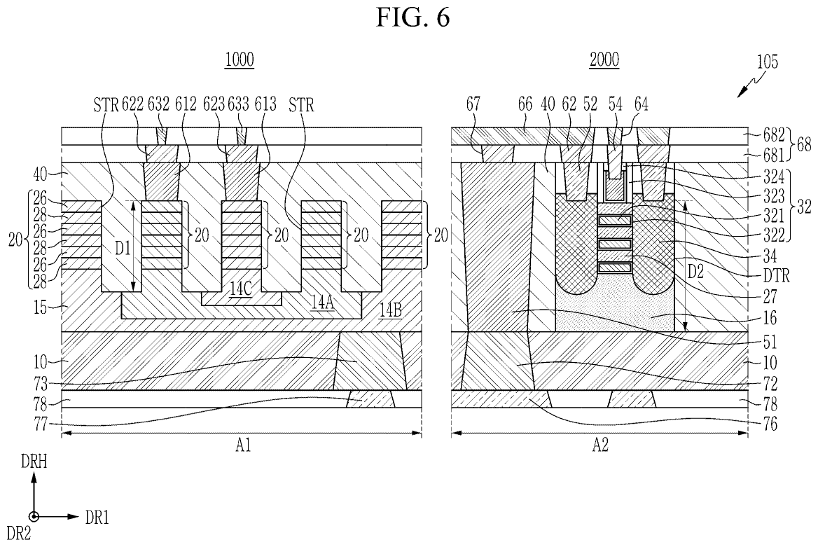

Hereinafter, a semiconductor device 105 according to an embodiment will be described with reference to FIG. 6. FIG. 6 illustrates a schematic cross-sectional view of a semiconductor device according to an embodiment.

Referring to FIG. 6, the semiconductor device 105 according to the present embodiment is similar to the semiconductor devices 100, 101, 102, 103, and 104 according to the embodiments described above. Detailed descriptions of the same components will be omitted.

Referring to FIG. 6, the semiconductor device 105 according to the present embodiment may include a first region A1 including the passive element 1000 and a second region A2 including the transistor 2000.

The passive element 1000 and the transistor 2000 may be on a base insulating layer 10. For example, the passive element 1000 may be a PNP or NPN junction element having a bulk-less structure, and the transistor 2000 may have a backside power distribution network (BSPDN) structure.

For a structure of the passive element 1000 and the transistor 2000 of the semiconductor device 105 according to the present embodiment, the above-described description of the passive element 1000 and the transistor 2000 of the semiconductor device 100 according to the previously described embodiment shown in FIG. 1 may be applied.

The passive element 1000 and the transistor 2000 may be on the base insulating layer 10.

The transistor 2000 may include an active pattern 16, a plurality of channel layers 27, a gate structure 32, and source and drain patterns 34 on the base insulating layer 10.

The passive element 1000 may include a third conductive region 14C as well as the semiconductor substrate 15 on the base insulating layer 10 and the first conductive region 14A and the second conductive region 14B in the nanosheet structure 20. The third conductive region 14C may have a same conductivity type as that of the second conductivity type region 14B.

The second conductive region 14B of the semiconductor substrate 15 may be on a first surface of the first conductive region 14A under the first conductive region 14A, and the third conductive region 14C of the semiconductor substrate 15 may be on a second surface of the first conductive region 14A above the first conductive region 14A.

Unlike in the passive element 1000 of the semiconductor devices 100, 101, 102, and 103 according to the embodiments described above, the passive element 1000 of the semiconductor device 105 according to the embodiment may be a PNP or NPN junction element.

However, unlike in the semiconductor device 104 according to the previously described embodiment of FIG. 5, instead of the first contact via 611, the second contact via 621, and the third contact via 631, the semiconductor device 105 according to the present embodiment may be connected to the second conductive region 14B of the passive element 1000 through a first back contact via 73 in the base insulating layer 10 and a second back contact via 77 in the back insulating layer 78, and a predetermined electrical signal may be applied from the outside to the second conductive region 14B.

According to the embodiment, the first region A1 of the semiconductor device 105 may have the separation trench STR that extends in the height direction DRH through the nanosheet structure 20 and a portion of the semiconductor substrate 15, and the second region A2 of the semiconductor device 105 may have the insulating trench DTR that extends in the height direction DRH through the active pattern 16 having a same layer as the semiconductor substrate 15 and the channel layers 27 having same layers as a portion of the nanosheet structure 20.

The separation trench STR may have a first depth D1 in the height direction DRH from an upper surface of the nanosheet structure 20, the insulation trench DTR may have a second depth D2 in the height direction DRH from an upper surface of an uppermost layer of the channel layers 27, the second depth D2 may be different from the first depth D1, and the second depth D2 may be greater than the first depth D1.

The first conductive region 14A, the second conductive region 14B, and the third conductive region 14C of the passive element 1000 may be separated from each other by the insulating layer 40 in the separation trench STR, and the transistor 2000 may be separated from other semiconductor elements by the insulating layer 40 in the insulating trench DTR.

The first region A1 including the passive element 1000 may have a separation trench STR having a relatively low first depth D1 so that a portion of the semiconductor substrate 15 may remain. Accordingly, the first conductive region 14A, the third conductive region 14B, and the third conductive region 14C may be formed in the remaining semiconductor substrate 15, and this allows the passive element 1000 to have the bulk-less structure.

The second region A2 where the transistor 2000 is located may include an insulating trench DTR having a second depth D2 in the height direction DRH that penetrates the substrate and has a relatively deep second depth, so that no substrate may be left around the transistor 2000, allowing for a back-side power distribution network (BSPDN) structure.

In this way, the semiconductor device 105 according to the present embodiment may include the passive element 1000 in the first region A1 and the transistor 2000 including the channel layer 27 in the form of a nanosheet in the second region A2, and may have a bulk-less structure and a back-end power distribution network (BSPDN) structure.

Many of the features of the semiconductor devices 100, 101, 102, 103, and 104 according to the above-described embodiment are all applicable to the semiconductor device 105 according to the present embodiment.

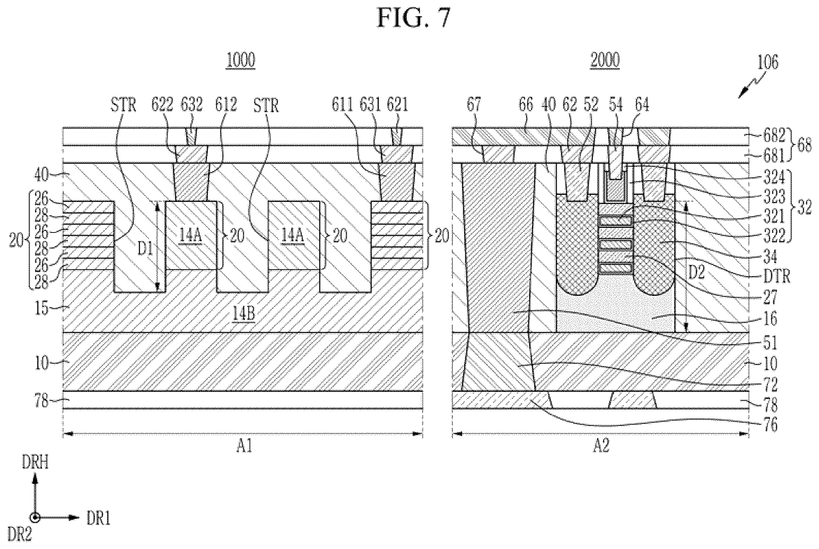

Hereinafter, a semiconductor device 106 according to an embodiment will be described with reference to FIG. 7. FIG. 7 illustrates a schematic cross-sectional view of a semiconductor device according to an embodiment.

Referring to FIG. 7, the semiconductor device 106 according to the present embodiment is similar to the semiconductor devices 100, 101, 102, 103, 104, and 105 according to the embodiments described above in FIGS. 1-6, respectively. Detailed descriptions of the same components will be omitted.

Referring to FIG. 7, the semiconductor device 106 according to the present embodiment may include a first region A1 including the passive element 1000 and a second region A2 including the transistor 2000.

The passive element 1000 and the transistor 2000 may be on a base insulating layer 10. For example, the passive element 1000 may be a PN diode having a bulk-less structure, and the transistor 2000 may have a backside power distribution network (BSPDN) structure.

For a structure of the passive element 1000 and the transistor 2000 according to the present embodiment, the above-described description of the passive element 1000 and the transistor 2000 of the semiconductor device 100 according to the previously described embodiment of FIG. 1 may be applied.

However, unlike in the semiconductor device 100 according to the previously described embodiment, the semiconductor device 106 according to the present embodiment may have the first conductive region 14A not formed on the semiconductor substrate 15, but it may be a region grown upward from the second conductive region 14B.

According to the embodiment, the semiconductor device 106 includes a first region A1 including the passive element 1000 and a second region A2 in including the transistor 2000, and the passive element 1000 and the transistor 2000 may be on the base insulation layer 10.

The passive element 1000 may include a second conductive region 14B in the semiconductor substrate 15 and a nanosheet structure 20 on the base insulating layer 10, and a first conductive region 14A grown on the second conductive region 14B while in contact with the second conductive region 14B.

The transistor 2000 may include an active pattern 16, a plurality of channel layers 27, a gate structure 32, and source and drain patterns 34 on the base insulating layer 10.

The first region A1 may have the separation trench STR that extends in the height direction DRH through the nanosheet structure 20 and a portion of the semiconductor substrate 15, and the second region A2 may have the insulating trench DTR that extends in the height direction DRH through the active pattern 16 of a same layer as the semiconductor substrate 15 and the channel layers 27 of same layers as a portion of the nanosheet structure 20. The separation trench STR may have a first depth D1 in the height direction DRH from an upper surface of the nanosheet structure 20, the insulation trench DTR may have a second depth D2 in the height direction DRH from an upper surface of an uppermost layer of the channel layers 27, the second depth D2 may be different from the first depth D1, and the second depth D2 may be greater than the first depth D1.

The first conductive region 14A and the second conductive region 14B of the passive element 1000 may be separated from each other by the insulating layer 40 in the separation trench STR, and the transistor 2000 may be separated from other semiconductor elements by the insulating layer 40 in the insulating trench DTR.

The first region A1 including the passive element 1000 may have a separation trench STR having a relatively low first depth D1 so that a portion of the semiconductor substrate 15 may remain. Accordingly, the first conductive region 14A and the second conductive region 14B may be formed in the remaining semiconductor substrate 15, and this allows the passive element 1000 to have the bulk-less structure.

The second region A2 where the transistor 2000 is located may include an insulating trench DTR having a second depth D2 that penetrates the substrate and has a relatively deep second depth, so that no substrate may be left around the transistor 2000, allowing for a back-side power distribution network (BSPDN) structure.

In this way, the semiconductor device 106 according to the present embodiment may include the passive element 1000 in the first region A1 and the transistor 2000 including the channel layer 27 in the form of a nanosheet in the second region A2, and may have a bulk-less structure and a back-end power distribution network (BSPDN) structure.

Many of the features of the semiconductor devices 100, 101, 102, 103, 104, and 105 according to the above-described embodiments are all applicable to the semiconductor device 106 according to the present embodiment.

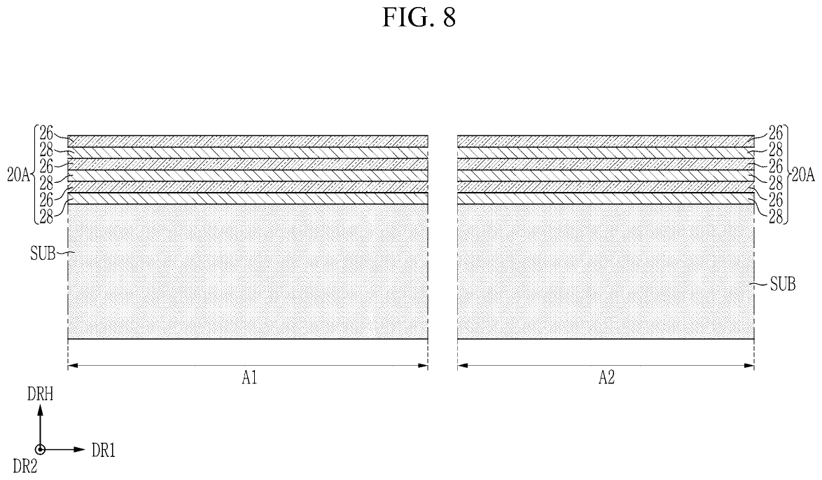

A manufacturing method for a semiconductor device according an embodiment will be described with reference to FIG. 8 to FIG. 13. FIG. 8 to FIG. 13 each illustrate an intermediate process in an example manufacturing method for a semiconductor device according to an embodiment.

Referring to FIG. 8, a nanosheet layer 20A may be stacked in the height direction DRH on a substrate SUB of the first region A1 and the second region A2 on which the passive element 1000 and the transistor 2000 are to be formed.

The substrate SUB may be a bulk substrate including a semiconductor material or a semiconductor-on-insulator. For example, the substrate SUB may include at least one of a group IV semiconductor, a group III-V compound semiconductor, or a group II-VI compound semiconductor. For example, the substrate SUB may include at least one of Si, Ge, SiGe, SiC, GaAs, InAs, or InP. For example, the semiconductor-on-insulator may be a silicon-on-insulator (SOI) or a silicon-germanium-on-insulator (SGOI).

The nanosheet layer 20A may include a plurality of first layers 26 and a plurality of second layers 28 that are alternately stacked in the height direction DRH.

The first layers 26 and the second layers 28 may be formed by epitaxial growth. The first layers 26 and the second layers 28 may include a semiconductor material. For example, the first layers 26 may include silicon (Si), and the second layers 28 may include silicon germanium (SiGe).

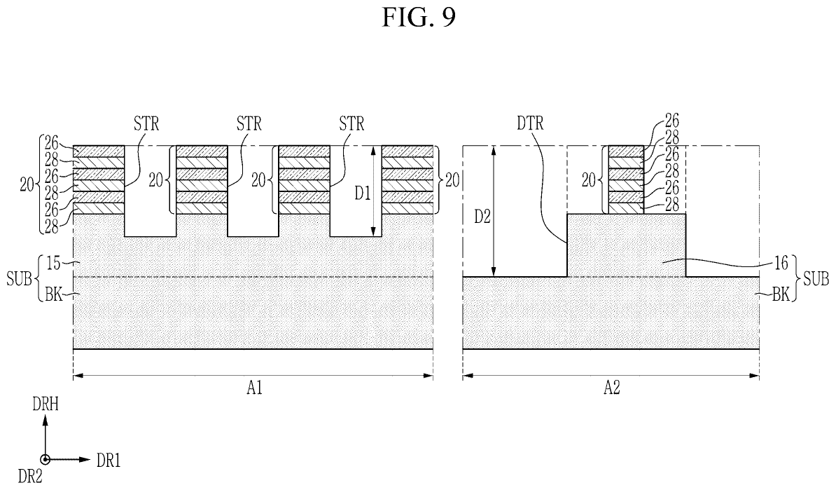

Referring to FIG. 9, one or more separation trenches STR may be formed in the first region A1, and one or more insulating trenches DTR may be formed in the second region A2.

A bulk portion BK, a semiconductor substrate 15 on the bulk portion BK, and a nanosheet structure 20 on the semiconductor substrate 15 may be formed by forming the separation trench STR in the first layers 26 and the second layers 28 of the first region A1, and a portion of the substrate SUB.

The bulk portion BK, an active pattern 16 on the bulk portion BK, and a nanosheet structure 20 on the active pattern 16 may be formed by forming the insulating trench DTR in the first layers 26 and the second layers 28 of the second region A2, and a portion of the substrate SUB. The active pattern 16 may be separated along the first direction DR1 and the second direction DR2, which are horizontal directions, by the insulating trench DTR.

The separation trench STR may have a first depth D1 in the height direction DRH, and the insulating trench DTR may have a second depth D2 in the height direction DRH. The second depth D2 may be different from the first depth D1, and the second depth D2 may be greater than the first depth D1.

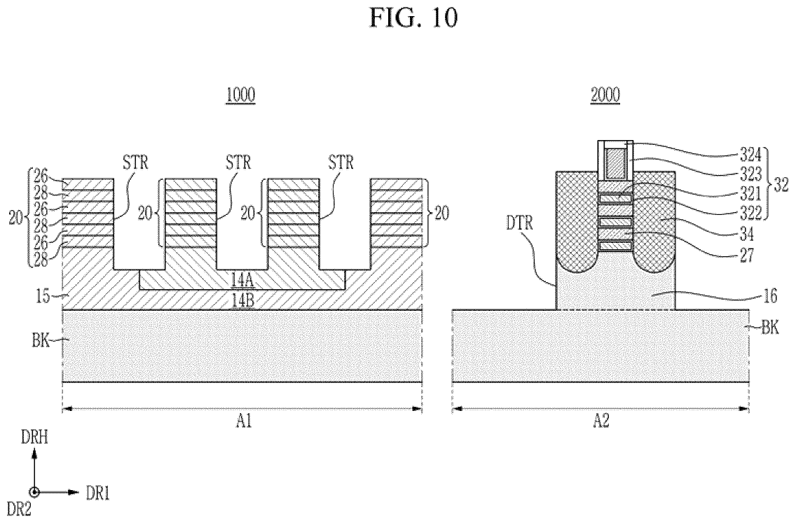

Referring to FIG. 10, the passive element 1000 may be formed in the first region A1, and the transistor 2000 may be formed in the second region A2. The passive element 1000 and the transistor 2000 may be formed on the bulk portion BK.

The passive element 1000 may be formed by doping a conductive impurity into the semiconductor substrate 15 and the nanosheet structure 20 in the first region A1. The first conductive region 14A may be formed by doping a first conductive dopant into portions of the semiconductor substrate 15 and the nanosheet structure 20, and the second conductive region 14B may be formed by doping other portions of the semiconductor substrate 15 and the nanosheet structure 20 with a second conductive dopant. However, the embodiment is not limited thereto, and the passive element 1000 may be the passive component 1000 of the semiconductor devices 100, 101, 102, 103, 104, 105, and 106 according to the embodiments described with reference to FIG. 1 to FIG. 7, respectively.

A channel region of the transistor 2000 may be formed in the active pattern 16 on the bulk portion BK. The channel layers 27 may be formed at a position corresponding to the first layers 26 of the nanosheet structure 20, and the gate electrode 321 and the gate insulating layer 322 between the channel layers 27 of the gate structure 32 of the transistor 2000 may be formed at a position corresponding to the second layers 28 of the nanosheet structure 20.

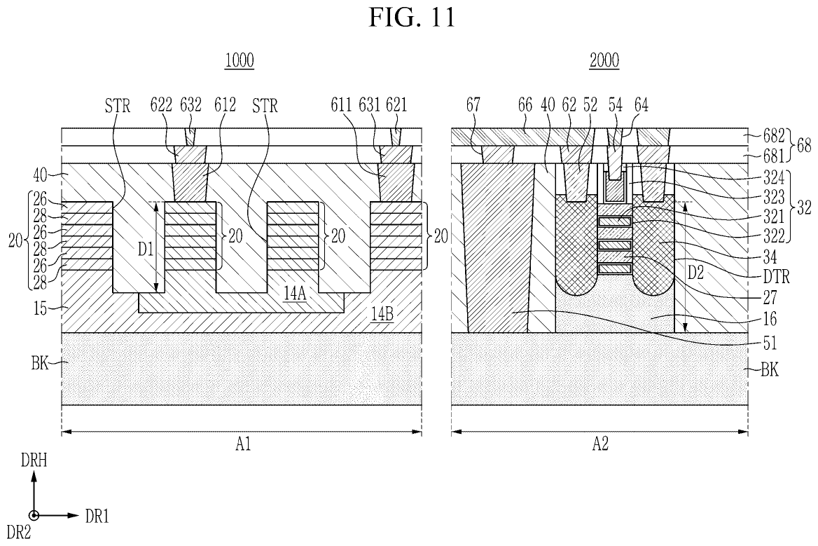

Referring to FIG. 11, by forming the insulating layer 40 of the first region A1 and the second region A2, the passive element 1000 and the transistor 2000 may be insulated, and the through-connector 51 extending in the height direction DRH through the front insulating layer 40, the front insulating layer 68 on the insulating layer 40, contact vias in the insulating layer 40 and the front insulating layer 68, and the front wiring layer 66 may be formed.

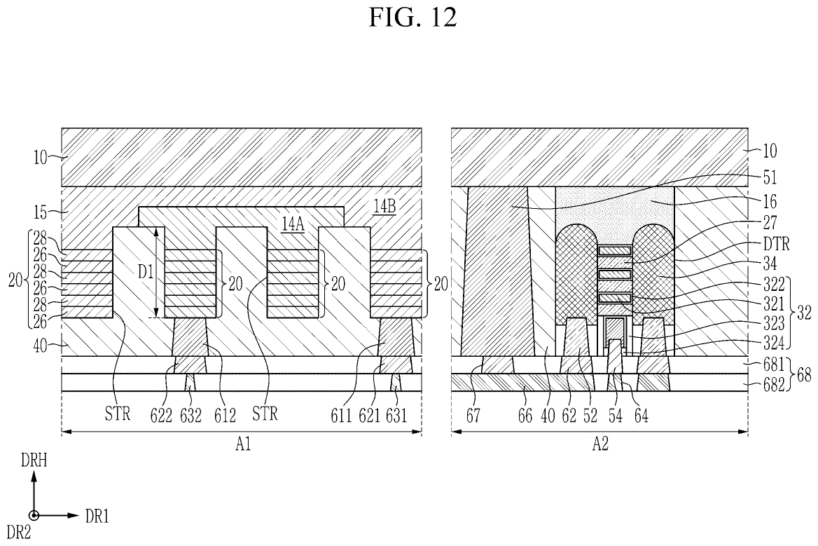

Referring to FIG. 12, after the bulk portion BK under the passive element 1000 and the transistor 2000 may be removed while being positioned at an upper portion, the base insulating layer 10 may be formed.

The bulk portion BK may be removed by an etching process using an etching material capable of selectively etching the substrate SUB. In this case, the etching process may not proceed smoothly in a region where the insulating layer 40 is present, so a back surface of the insulating layer 40 may function as a kind of etching stop surface. Accordingly, the bulk portion BK may be stably removed to the back surface of the insulating layer 40. However, the embodiment is not limited thereto, and the bulk portion BK may be removed by various processes such as a wet etching process and a chemical mechanical polishing (CMP) process.

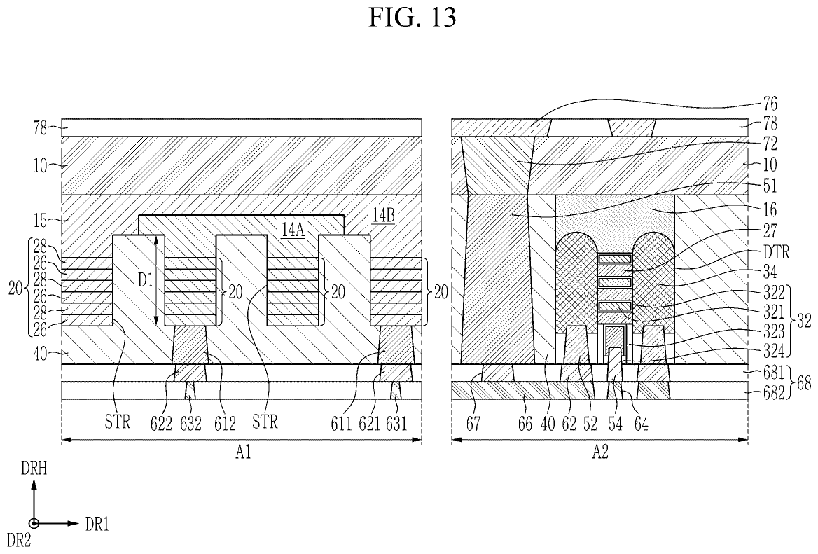

Referring to FIG. 13, the back contact via 72 may be formed in the base insulating layer 10, and the back insulating layer 78 may be formed on the base insulating layer 10 and on an exposed upper surface of the back contact via 72. The term “exposed” may be used herein to describe relationships between elements and/or with reference to intermediate processes in fabricating an integrated circuit device, but may not require exposure of a particular element in the completed device.

Next, the back wiring layer 76 in the back insulating layer 78 may be formed, thereby forming the semiconductor element 100 as shown in FIG. 1.

According to the embodiment, a passive element 1000, which includes regions doped with desired conductive impurities in the semiconductor substrate 15 and the nanosheet structure 20 of the first region A1, may be formed by forming a relatively small-depth separation trench STR in the first region A1, and a transistor 2000 including a channel region formed in the separated active pattern 16 and the channel layers 27 may be formed by forming a relatively large-depth insulating trench DTR in the second region A2.

According to the embodiment, after forming the passive element 1000 and the transistor 2000 in the first region A1 and the second region A2, by removing the bulk portion BK of the substrate SUB, a semiconductor device having a bulk-less structure and a backside power distribution network (BSPDN) structure may be formed.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor device, comprising:
a base insulating layer including a first region and a second region;
a passive element including a first conductive region and a second conductive region on the first region of the base insulating layer; and
a transistor on the second region of the base insulating layer,
wherein a portion of the first conductive region and a portion of the second conductive region of the passive element are separated by a first trench, the first trench extending, in a first direction perpendicular to a surface of the base insulating layer, through the portion of the first conductive region and the portion of the second conductive region,
the transistor is insulated from other semiconductor elements by a second trench, and
a second depth of the second trench in the first direction is greater than a first depth of the first trench in the first direction.

2. The semiconductor device of claim 1, wherein
at least one of the first conductive region or the second conductive region is in a semiconductor substrate on the base insulating layer and a nanosheet structure on the semiconductor substrate, and
the first trench extends in the first direction through the nanosheet structure and a portion of the semiconductor substrate.

3. The semiconductor device of claim 2, wherein
the second trench extends in the first direction to the base insulating layer.

4. The semiconductor device of claim 2, wherein
a channel region of the transistor includes an active pattern which is a same layer as a portion of the semiconductor substrate and a plurality of channel layers which are same layers as a portion of the nanosheet structure.

5. The semiconductor device of claim 2, wherein
the first conductive region is a region in which the semiconductor substrate and the nanosheet structure are doped with a dopant of a first conductive type, and
the second conductive region is a region in which the semiconductor substrate and the nanosheet structure are doped with a dopant of a second conductive type that is different from the first conductive type.

6. The semiconductor device of claim 5, wherein
the semiconductor substrate doped with the dopant of the first conductive type and the semiconductor substrate doped with the dopant of the second conductive type are in contact with the base insulating layer.

7. The semiconductor device of claim 6, further comprising:
a front wiring layer on the transistor;
a back wiring layer under the base insulating layer; and
a through-connector in the second trench,
wherein the transistor is electrically connected to the front wiring layer and the back wiring layer through the through-connector.

8. A semiconductor device, comprising:
a base insulating layer including a first region and a second region;
a passive element including a first conductive region and a second conductive region on the first region of the base insulating layer; and
a transistor on the second region of the base insulating layer,
wherein at least one of the first conductive region or the second conductive region is in a semiconductor substrate on the base insulating layer and a nanosheet structure on the semiconductor substrate.

9. The semiconductor device of claim 8, wherein
the first conductive region and the second conductive region are in contact with the base insulating layer.

10. The semiconductor device of claim 9, wherein
a channel region of the transistor includes an active pattern which is a same layer as a portion of the semiconductor substrate and a plurality of channel layers which are a same layer as a portion of the nanosheet structure.

11. The semiconductor device of claim 8, further comprising:
a front wiring layer on the transistor;
a back wiring layer under the base insulating layer; and
a through-connector configured to electrically connect the transistor to the front wiring layer and the back wiring layer.

12. The semiconductor device of claim 8, wherein
the first conductive region is a region in which the semiconductor substrate and the nanosheet structure are doped with a dopant of a first conductive type, and
the second conductive region is a region in which the semiconductor substrate and the nanosheet structure are doped with a dopant of a second conductive type that is different from the first conductive type.

13. The semiconductor device of claim 12, wherein
the region in which the semiconductor substrate is doped with the dopant of the first conductive type and the region in which the semiconductor substrate is doped with the dopant of the second conductive type are in contact with the base insulating layer.

14. A manufacturing method for a semiconductor device, the method comprising:
forming a nanosheet layer in which a plurality of first layers and a plurality of second layers are alternately stacked in a first direction on a substrate including a bulk region and an active region on the bulk region, the first direction is perpendicular to a surface of the substrate;
forming a first trench by removing portions of the nanosheet layer and the active region in the first region of the substrate;
forming a second trench by removing the nanosheet layer and the active region in the second region of the substrate;
forming a first conductive region and a second conductive region in the active region of the first region and the nanosheet layer;
forming a transistor including the active region of the second region and the second layers; and
removing the bulk region.

15. The manufacturing method of claim 14, further comprising
forming a base insulating layer in a region which the bulk region has been removed.

16. The manufacturing method of claim 15, wherein
forming the first conductive region and the second conductive region includes
forming the first conductive region by doping the semiconductor substrate and the nanosheet layer with a dopant of a first conductive type, and forming the second conductive region by doping the semiconductor substrate and the nanosheet layer with a dopant of a second conductive type that is different from the first conductive type.

17. The manufacturing method of claim 16, wherein
the semiconductor substrate doped with the dopant of the first conductive type and the semiconductor substrate doped with the dopant of the second conductive type are in contact with the base insulating layer.

18. The manufacturing method of claim 14, further comprising:
forming a through-connector in the second trench;
forming a front wiring layer on the transistor; and
forming a back wiring layer under the base insulating layer,
wherein the transistor is electrically connected to the front wiring layer and the back wiring layer through the through-connector.

19. The manufacturing method of claim 14, wherein
a portion of the first conductive region and a portion of the second conductive region are separated by the first trench,
the transistor is insulated by a second trench, and
a second depth of the second trench in the first direction is greater than a first depth of the first trench in the first direction.

20. The manufacturing method of claim 19, wherein
forming the second trench comprises removing an entire portion of the active region in the second region of the substrate.
